(19) United States
(12) Patent Application Publication
(10) Pub. No.: US 2008/0185569 A1
(43) Pub. Date: Aug. 7, 2008

(54) PHASE CHANGE RANDOM ACCESS MEMORIES INCLUDING A WORD LINE FORMED OF A METAL MATERIAL AND METHODS OF FORMING THE SAME

(75) Inventors: Myung-jin Park, Gyeonggi-do (KR); Young-tae Kim, Incheon (KR); Keun-ho Lee, Gyeonggi-do (KR)

Correspondence Address: MYERS BIGEL SIBLEY & SAJOVEC, PO BOX 37428, RALEIGH, NC, 27627, US

(73) Assignee: Samsung Electronics, Co., Ltd.

(21) Appl. No.: 12/023,474

(22) Filed: Jan. 31, 2008

(30) Foreign Application Priority Data
Feb. 7, 2007 (KR) 10-2007-0012768

(51) Int. Cl. H01L 47/00; H01L 21/00

(52) U.S. Cl. 257/2; 438/102; 257/E47.001; 257/E21.001

(57) ABSTRACT

A phase change memory includes a word line disposed on a semiconductor substrate and a cell diode that physically contacts the semiconductor substrate and a corresponding word line. The word line may be formed of a metal, such as tungsten. Accordingly, no metal contact is included and the word line formed of metal is in contact with the cell diode.

### CROSS-REFERENCE TO RELATED PATENT APPLICATION

This application claims the benefit of Korean Patent Application No. 10-2007-0012768, filed on Feb. 7, 2007 in the Korean Intellectual Property Office, the disclosure of which is incorporated herein in its entirety by reference.

### FIELD OF THE INVENTION

The present invention relates to semiconductor memory devices, and, more particularly, to phase change memory devices in which cell diodes and word lines are directly connected to each other without using a metal contact by including word lines formed of a metal, and methods of forming the same.

### BACKGROUND OF THE INVENTION

A phase change memory is a memory device that stores data by changing the electrical resistance according to the crystalline state of a material, such as, for example, chalcogenide. When the temperature of a phase change layer, which is formed of a phase change material, is increased up to its melting point by applying a high current pulse to the phase change layer for a short period of time and then the phase change layer is rapidly cooled, the phase change layer is converted to an amorphous state having a high resistance (reset state). On the other hand, when a low current pulse is applied to the phase change layer and the phase change layer is maintained at a crystallization temperature for several tens of nanoseconds and then cooled, the phase change layer is converted to a crystalline state having a low resistance (set state).

FIG. 1 is a schematic view of a cell array of a conventional phase change memory 100. Referring to FIG. 1, each cell CP of a memory cell array CA of the phase change memory 100 includes a cell diode D connected to a word line WL, and a phase change material Rp connected serially between a bit line BL and the cell diode D.

FIG. 2 is a cross-sectional view of a conventional phase change memory 200. Referring to FIG. 2, a word line WL of the phase change memory 200 is formed of a high density n-type semiconductor layer (n+) by implanting predetermined ions in a p-type semiconductor substrate. Diodes are formed on the word line WL. The phase change memory 200 includes one metal contact MC corresponding to eight diodes sharing the word line WL.

In the conventional phase change memory, a predetermined voltage is applied to the metal contact corresponding to the word line to activate the word line. One diode of the eight diodes connected to the activated word line is selected to be connected to an activated bit line.

The surface area of the conventional phase change memory having an activated word line using the above metal contact may be increased due to the metal contact. Also, it may be difficult to control the selection of diodes that are relatively far from the metal contact.

### SUMMARY

According to some embodiments of the present invention, a phase change memory includes a word line disposed on a semiconductor substrate and a cell diode that physically contacts the semiconductor substrate and a corresponding word line.

The word line may be formed of a metal and the metal may be tungsten in some embodiments.

The semiconductor substrate may have a first conductivity type and the cell diode may include a low density, second conductivity type semiconductor region, which is doped to a low density, and a high density, first conductivity type semiconductor region, which is doped to a high density, and formed on the second conductivity type semiconductor region. The first conductivity type may be p-type and the second conductivity type may be n-type.

The cell diode may be in contact with a side of the word line. Cell diodes disposed adjacent to each other on the same word line may be defined as first and second cell diodes, wherein the first diode is formed to be in contact with a first side of the word line, and the second cell diode is formed to be in contact with a second side of the word line.

The word line and the cell diode may be formed on the same layer. The phase change memory may not comprise a metal contact.

The phase change memory may further include a phase change material formed on the top of the cell diode and a bit line disposed on the top of the phase change material.

According to further embodiments of the present invention, there is provided a method of manufacturing a phase change memory, the method including forming a word line on a semiconductor substrate and forming a cell diode that physically contacts the semiconductor substrate and the word line.

Forming the word line may include forming an etch stop layer on the semiconductor substrate, forming a first interlayer insulating layer on the etch stop layer, etching a predetermined portion of the first interlayer insulating layer, and depositing the word line on the etched portion of the first interlayer insulating layer.

Forming the cell diode may include forming a second interlayer insulating layer on the first interlayer insulating layer, etching a predetermined region of the first interlayer insulating layer, the second interlayer insulating layer, and the word line, and depositing the cell diode in the etched region.

The semiconductor substrate may be exposed using a photoresist pattern as an etching mask. The etched region may be in contact with a side of the word line. The predetermined region may be etched using an etching selectivity such that all the materials comprising the first interlayer insulating layer, the second interlayer insulating layer, and the word line are etched.

The semiconductor substrate may have a first conductivity type and depositing the cell diode may include forming a low density, second conductivity type semiconductor region, which is doped to a low density, on the semiconductor substrate, and forming a high density, first conductivity type semiconductor region, which is doped to a high density, on the second conductivity type semiconductor region. The second conductivity type semiconductor region and the first conductivity type semiconductor region may be formed using an epitaxial growth method. The first conductivity type may be p-type and the second conductivity type may be n-type.

Thus, embodiments of the present invention may provide a phase change memory with reduced surface area and improved electrical characteristics. Moreover, embodiments of the present invention may also provide methods of manufacturing phase change memory devices with reduced surface area and improved electrical characteristics.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view of a cell array of a conventional phase change memory;

FIG. 2 is a cross-sectional view of a conventional phase change memory;

FIG. 3 is a schematic view illustrating a layout of a phase change memory according to some embodiments of the present invention;

FIG. 4 is a plan view of the layout of the phase change memory of FIG. 3;

FIG. 5 is a table that summarizes electrical characteristics of the phase change memory of FIG. 3; and

FIG. 6 illustrates methods of manufacturing the phase change memory of FIG. 3, according to some embodiments of the present invention.

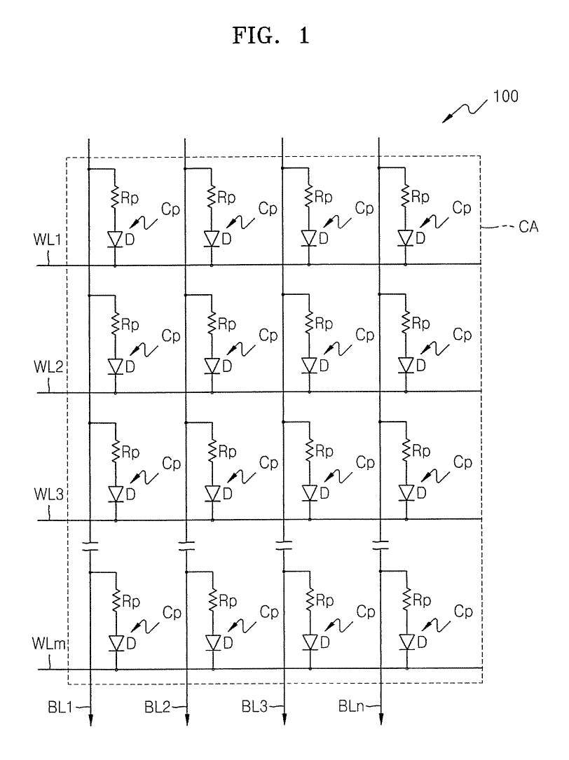

### DETAILED DESCRIPTION OF EMBODIMENTS OF THE INVENTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled.

As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure. The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

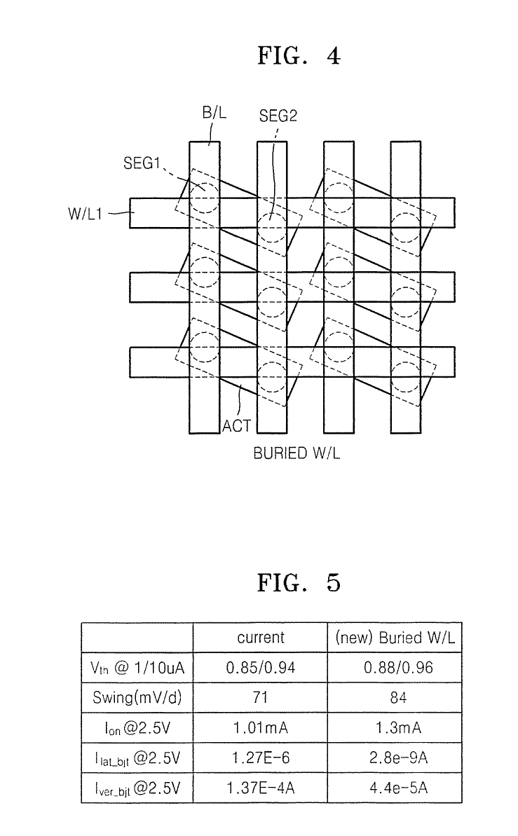

FIG. 3 is a schematic view illustrating a layout of a phase change memory according to some embodiments of the present invention and FIG. 4 is a plan view of the layout of the phase change memory of FIG. 3 Referring to FIGS. 3 and 4, the phase change memory 300 includes semiconductor substrates ACT, word lines WL, and cell diodes SEG. The word lines WL are disposed on a first conductivity type semiconductor substrate ACT. The cell diodes SEG are physically in contact with the semiconductor substrate ACT and corresponding word lines.

The cell diodes SEG comprise a low density second conductivity type (n−) semiconductor region and a high density first conductivity type (p+) semiconductor region. The high density first conductivity type (p+) semiconductor region is formed on the second conductivity type (n−) semiconductor region. The first conductivity type semiconductor region may be a p-type region, and the second conductivity type semiconductor region may be an n-type region. In other words, the cell diodes SEG may be junction diodes.

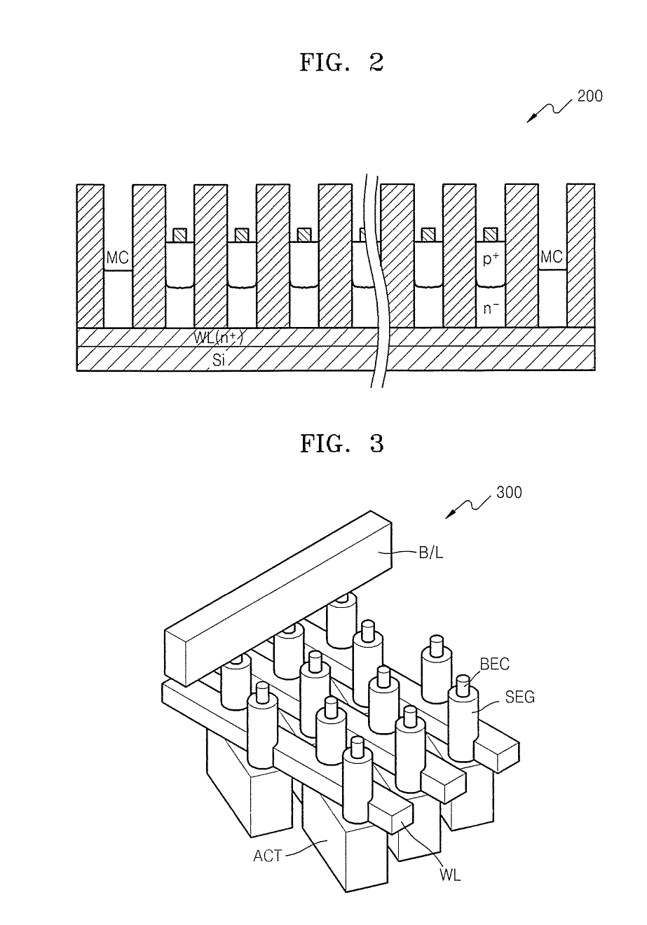

The word lines WL, according to some embodiments of the present invention, are formed of a metal unlike the word lines in the conventional art (see FIG. 2). The metal may be tungsten according to some embodiments of the present invention. Also, the word lines WL, according to some embodiments of the present invention, are formed outside of the semiconductor, that is, on the semiconductor substrate unlike the word lines in the conventional art (see FIG. 2). The word lines WL may be formed on the same layer as the cell diodes SEG.

Thus, the phase change memory 300, according to some embodiments of the present invention, can activate word lines without using a metal contact as the word lines WL are formed of a metal on the semiconductor substrate so as to be in contact with the cell diodes SEG.

Accordingly, the phase change memory 300, according to some embodiments of the present invention, does not include a metal contact, which is typically needed in the conventional art for every eight diodes. As a result, integration can be increased by about 20%. According to some embodiments of the present invention, the number of net dies produced in a 90 nm process can be increased from the present 140-150 up to about 180.

Also, the phase change memory 300, according to some embodiments of the present invention, does not include a metal contact and, thus, the problem of controlling of the selection of the diodes according to resistance between a metal contact and the diodes discussed above with respect to FIG. 2 may be lessened or eliminated.

Referring again to FIGS. 3 and 4, the cell diodes SEG are in contact with a side of the word lines WL. When the cell diodes, which are in contact with the same word line WL, are defined as first and second cell diodes SEG1 and SEG2, the first cell diode SEG1 is formed to be in contact with a first side of the word line WL1, and the second cell diode SEG2 is formed to be in contact with a second side of the word line WL1.

Thus, the phase change memory 300 includes cell diodes that are arranged in a zigzag fashion to be in contact with a side of the word lines, which may improve the characteristics of the word lines, according to some embodiments of the present invention, and may improve control over selection of the diodes.

FIG. 5 is a table that summarizes electrical characteristics of the phase change memory 300 of FIG. 3 in comparison with the conventional art. Referring to FIG. 5, at a voltage of 2.5 V, the cell current ION of the phase change memory device 300 is increased to 1.3 mA from 1.01 mA exhibited by the conventional art. The phase change memory may require a relatively high current to heat the phase change material above its melting point, and, thus, such an increase in the cell current may be advantageous.

Also, referring to FIG. 5, BJY current (Ilat_bjt, Iver_bjt) denoting leakage current may be decreased according to some embodiments of the present invention. Thus, as can be seen from FIG. 5, the electrical characteristics of the phase change memory according to the present invention may be improved.

Referring again to FIG. 3, the phase change memory 300 further includes a phase change material (GST) formed on the cell diodes SEG and bit lines BL on the phase change material. In some embodiments, the phase change material is formed of a chalcogenide material comprising germanium (Ge), antimony (Sb), and/or tellurium (Te). A device (BEC) may be used to heat the phase change material (GST). The phase change material (GST) is located on top of the BEC.

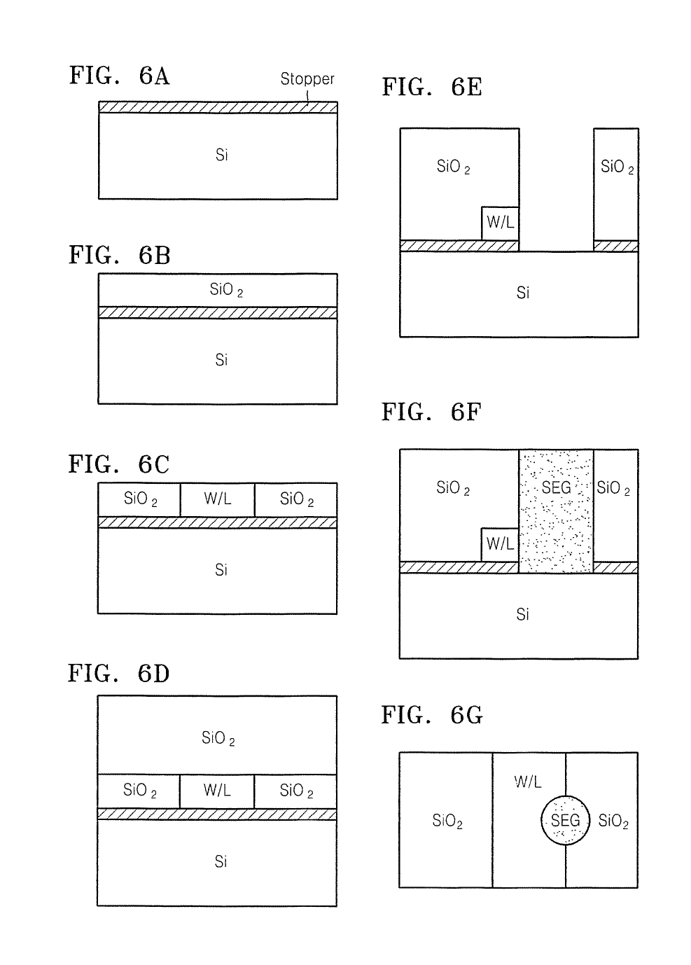

Hereinafter, methods of manufacturing the phase change material of FIG. 3, according to some embodiments of the present invention, will be described. FIG. 6 illustrates methods of manufacturing the phase change memory of FIG. 3, according to some embodiments of the present invention.

Referring to FIG. 6, methods of manufacturing the phase change memory 300, according to some embodiments of the present invention, comprises forming an etch stop layer on an activated semiconductor substrate (Si) as illustrated in FIG. 6(a) and then forming a first interlayer insulating layer (SiO₂) on the etch stop layer as illustrated in FIG. 6(b).

A photoresist pattern (not shown) is then used as an etching mask to expose the etch stop layer to remove portions of the first interlayer insulating layer (SiO₂). After patterning positions for word lines WL, a metal is deposited in the patterned positions to form word lines WL as illustrated in FIG. 6(c). As described above, the metal may be tungsten.

After the word lines WL are formed as shown in FIG. 6(c), a second interlayer insulating layer (SiO₂) is formed on the first interlayer insulating layer as illustrated in FIG. 6(d) of FIG. 6. The semiconductor substrate (Si) is exposed using a photoresist pattern (not shown) as an etching mask, and, thus, portions of the first interlayer insulating layer and the second interlayer insulating layer are removed as illustrated in FIG. 6(e).

Removing portions of the first and second interlayer insulating layers exposes a side of the word lines. That is, the structure of FIG. 6(d) is patterned so that the word lines are exposed, as in FIG. 6(e). Accordingly, the structure may be patterned by using etching selectivity, such that all the materials forming the first and second interlayer insulating layers and the word lines can be etched.

Referring to FIG. 6, after a position for the cell diodes is patterned as shown in FIG. 6(e), a semiconductor layer is grown to form the cell diodes SEG as in FIG. 6(f). The cell diodes SEG may be formed to include a low density second conductivity type (n−) semiconductor region and a high density first conductivity type (p+) semiconductor region. The cell diodes of the phase change memory, according to some embodiments of the present invention, can be formed using an epitaxial growth method. FIG. 6(g) is a plan view of the word line and the cell diode formed in the above described manner.

Though FIG. 6 does not illustrate growing a semiconductor substrate, forming an active region in the semiconductor substrate, masking using a photoresist, or depositing or planarizing the cell diodes, these operations are generally understood by those of skill in the art and are included in the methods of manufacturing the phase change memory according to some embodiments of the present invention. Also, though FIG. 6 does not illustrate forming of a phase change material or bit lines formed on the cell diodes, this process is also generally understood by those of ordinary skill in the art and, thus, is omitted.

As described above, embodiments of the present invention have been described in the drawings and the specification. However, the terms used herein are only for illustrative purposes only and are not intended to limit the meaning or the range of the present invention as defined in the attached claims.

For example, the phase change memory according to some embodiments of the present invention includes cell diodes; however, the cell diodes can be replaced with cell transistors. Also, the cell diodes formed adjacent to the same word line are described as being formed in a zigzag fashion; however, the cell diodes may be arranged linearly according to other embodiments of the present invention.

As described above, according to some embodiments of the present invention, a phase change memory can be provided with reduced surface area and improved electrical characteristics by forming word lines that are formed of a metal, such as tungsten, and are in contact with cell diodes on a semiconductor substrate without including metal contacts.

While the present invention has been particularly shown and described with reference to exemplary embodiments thereof, it will be understood by those of ordinary skill in the art that various changes in form and details may be made therein without departing from the spirit and scope of the present invention as defined by the following claims.

That which is claimed:

1. A phase change memory, comprising:
a word line disposed on a semiconductor substrate; and
a cell diode that physically contacts the semiconductor substrate and a corresponding word line.

2. The phase change memory of claim 1, wherein the word line comprises a metal.

3. The phase change memory of claim 2, wherein the metal is tungsten.

4. The phase change memory of claim 1, wherein the semiconductor substrate is a first conductivity type semiconductor substrate, and wherein the cell diode comprises:
a low density, second conductivity type semiconductor region, which is doped to a low density; and
a high density, first conductivity type semiconductor region, which is doped to a high density and is disposed on the second conductivity type semiconductor region.

5. The phase change memory of claim 4, wherein the first conductivity type is p-type, and the second conductivity type is n-type.

6. The phase change memory of claim 1, wherein the cell diode is in contact with a side of the word line.

7. The phase change memory of claim 6, wherein cell diodes disposed adjacent to each other on the same word line are defined as first and second cell diodes, wherein the first diode is in contact with a first side of the word line, and the second cell diode is in contact with a second side of the word line.

8. The phase change memory of claim 1, wherein the word line and the cell diode are formed on the same layer.

9. The phase change memory of claim 1, wherein the phase change memory does not comprise a metal contact.

10. The phase change memory of claim 1, further comprising:
a phase change material disposed on the top of the cell diode; and
a bit line disposed on the top of the phase change material.

11. A method of manufacturing a phase change memory, comprising:
forming a word line on a semiconductor substrate; and
forming a cell diode that physically contacts the semiconductor substrate and the word line.

12. The method of claim 11, wherein the word line comprises a metal.

13. The method of claim 12, wherein the metal is tungsten.

14. The method of claim 11, wherein forming the word line comprises:
forming an etch stop layer on the semiconductor substrate;
forming a first interlayer insulating layer on the etch stop layer;
etching a predetermined portion of the first interlayer insulating layer; and
depositing the word line on the etched portion of the first interlayer insulating layer.

15. The method of claim 14, further comprising:
exposing the etch stop layer using a photoresist pattern as an etching mask.

16. The method of claim 14, wherein forming the cell diode comprises:
forming a second interlayer insulating layer on the first interlayer insulating layer;
etching a predetermined region of the first interlayer insulating layer, the second interlayer insulating layer, and the word line; and
depositing the cell diode in the etched region.

17. The method of claim 16, further comprising:
exposing the semiconductor substrate using a photoresist pattern as an etching mask.

18. The method of claim 16, wherein the etched region is in contact with a side of the word line.

19. The method of claim 16, wherein in the etching the predetermined region comprises etching the predetermined region using an etching selectivity such that all materials comprising the first interlayer insulating layer, the second interlayer insulating layer, and the word line are etched.

20. The method of claim 16, wherein the semiconductor substrate has a first conductivity type and wherein depositing the cell diode comprises:
forming a low density, second conductivity type semiconductor region, which is doped to a low density, on the semiconductor substrate; and
forming a high density, first conductivity type semiconductor region, which is doped to a high density, on the second conductivity type semiconductor region,
wherein the low density, second conductivity type semiconductor region and the high density, first conductivity type semiconductor region are formed using an epitaxial growth method.
